(19) United States
(12) Patent Application Publication
(10) Pub. No.: US 2025/0153122 A1
(43) Pub. Date: May 15, 2025

(54) CHEMICAL LIQUID EXCHANGE METHOD, CHEMICAL LIQUID SUPPLY SYSTEM, AND CHEMICAL LIQUID RECYCLING METHOD

(71) Applicant: SAMSUNG ELECTRONICS CO., LTD., Suwon-si (KR)

(72) Inventors: SUNGHYUN PARK, Suwon-si (KR); Minsuk KANG, Suwon-si (KR); Young-Hoo KIM, Suwon-si (KR); Jinseon YOU, Suwon-si (KR); Tae-Hong KIM, Suwon-si (KR); Woogwan SHIM, Suwon-si (KR)

(73) Assignee: SAMSUNG ELECTRONICS CO., LTD., Suwon-si (KR)

(21) Appl. No.: 18/741,245

(22) Filed: Jun. 12, 2024

(30) Foreign Application Priority Data
Nov. 15, 2023 (KR) 10-2023-0157970

(51) Int. Cl. B01F 35/221; B01F 35/21; B01F 35/90; B01F 35/92; B01F 101/58; H01L 21/67

(52) U.S. Cl. CPC B01F 35/2215; B01F 35/2132; B01F 35/92; B01F 2035/99; B01F 2101/58; H01L 21/67017

(57) ABSTRACT

A chemical liquid exchange method includes: recovering, by a first recycling tank, a first portion of a first chemical liquid that was previously used in a chamber; recovering, by a second recycling tank, a second portion of the first chemical liquid that was previously used in the chamber; supplying, from the first recycling tank, the first portion of the first chemical liquid to a first sub-tank; draining, from the second recycling tank, the second portion of the first chemical liquid; supplying, from the first sub-tank, the first portion of the first chemical liquid to a main tank; and receiving, by a second sub-tank, a second chemical liquid from an outside; and supplying, from the second sub-tank, the second chemical liquid to the main tank.

### CROSS-REFERENCE TO RELATED APPLICATION

This application claims priority to and the benefit of Korean Patent Application No. 10-2023-0157970, filed in the Korean Intellectual Property Office on Nov. 15, 2023, the entire contents of which are incorporated herein by reference.

### BACKGROUND

### 1. Technical Field

Embodiments of the present disclosure relate to a chemical liquid exchange method, a chemical liquid supply system, and a chemical liquid recycling method.

### 2. Description of Related Art

A semiconductor device is formed by undergoing processing process on a substrate such as a deposition process that deposits a thin film of a specific material on the substrate, a photo process that selectively exposes the thin film by using a photosensitive material, and an etching process that forms a pattern by removing the thin film from the selectively exposed portion.

The semiconductor etching process is a process that forms a semiconductor circuit by engraving a pattern on the substrate and a photosensitive film (PR) formed in the photo process is used as a barrier mask to remove underlying films of portions without the PR and to leave certain patterns. If the circuit is broken due to the incorrect etching or the circuit is not uniform, errors occur in the produced semiconductor chip, which negatively impacts a yield.

A type of etching may be wet etching or dry etching based on materials that cause the etching reaction. The wet etching includes etching a thin film by using a liquid chemical material. When the substrate is immersed in a chemical solution, a reaction occurs only at the area where the solution and the thin film material come into contact, and then the thin film material may be removed. The wet etching is widely used in the semiconductor processes.

The wet etching process is classified into a batch type and a single type depending on the processing method, and the batch type has drawbacks such as poor dispersions, flow defect issues, and difficulties in controlling a selectivity. Recently, a single type equipment that cleans each sheet is being developed, and the single type has merits of avoiding cross-contamination problems and increasing a uniformity and yield of the cleaning.

### SUMMARY

In a comparative chemical liquid exchange process, where a reused chemical liquid is drained and then exchanged for a new chemical liquid, a process of draining all of the reused chemical liquid and then filling with the new chemical liquid took a long time, and other processes related to the chemical liquid supply could not proceed during the time of preparing the new chemical liquid. In contrast, in embodiments of the present disclosure, only some tanks of the reused chemical liquid are drained, and the remaining tanks supply the chemical liquid to a main tank for reuse.

According to embodiments of the present disclosure, a chemical liquid exchange method is provided that improves a loss rate due to a facility stoppage by preventing a chemical liquid supply device from stopping while preparing the new chemical liquid by filling with the new chemical liquid during the supplying for the reuse.

In addition, if a Si concentration in the chemical liquid supplied to a chamber is outside a reference range, process defects or equipment problems may occur. In contrast, according to embodiments of the present disclosure, a chemical liquid supply system is provided that maintains a homeostasis of the process/equipment by controlling the concentration of Si in the chemical liquid depending on a measured value by measuring the Si concentration of the chemical liquid supplied from the main tank to the chamber.

According to embodiments of the present disclosure, a chemical liquid recycling method is provided that may shorten a time required to raise the temperature of the reused chemical liquid. by first intensively recovering the chemical liquid from one recycling tank, and by heating the recovered chemical liquid in a recycling unit and then supplying it to a supply unit.

According to embodiments of the present disclosure, a chemical liquid exchange method is provided and includes: recovering, by a first recycling tank, a first portion of a first chemical liquid that was previously used in a chamber; recovering, by a second recycling tank, a second portion of the first chemical liquid that was previously used in the chamber; supplying, from the first recycling tank, the first portion of the first chemical liquid to a first sub-tank; draining, from the second recycling tank, the second portion of the first chemical liquid; supplying, from the first sub-tank, the first portion of the first chemical liquid to a main tank; and receiving, by a second sub-tank, a second chemical liquid from an outside; and supplying, from the second sub-tank, the second chemical liquid to the main tank.

According to embodiments of the present disclosure, a chemical liquid supply system is provided and includes: a first recycling tank connected to a chamber and configured receive, from the chamber, a first portion of a first chemical liquid that was used in the chamber; a second recycling tank connected to the chamber and configured receive, from the chamber, a second portion of the first chemical liquid that was used in the chamber; a first sub-tank connected to the first recycling tank and configured to receive the first portion of the first chemical liquid from the first recycling tank; a second sub-tank configured to receive a second chemical liquid from a second chemical liquid supply; a main tank connected to the first sub-tank and the second sub-tank, the main tank configured to receive the first portion of the first chemical liquid from the first sub-tank and the second chemical liquid from the second sub-tank, and obtain a third chemical liquid by the first portion of the first chemical liquid and the second chemical liquid mixing in the main tank; a third chemical liquid supply configured to supply the third chemical liquid from the main tank to the chamber; a first Si measurer in the third chemical liquid supply and configured to measure a Si concentration of the third chemical liquid supplied to the chamber; and a controller configured to control an amount of SiO₂ included in the second chemical liquid supplied to the second sub-tank based on a measured Si concentration of the third chemical liquid.

According to embodiments of the present disclosure, a method of recovering and reusing a chemical liquid is provided and includes: recovering a first chemical liquid from a chamber by one from among a first recycling tank and a second recycling tank of a recycling unit; supplying the first chemical liquid to a supply unit, that includes at least one sub-tank, after raising a temperature of the first chemical liquid in the one from among the first recycling tank and the second recycling tank; and supplying, from the supply unit, the first chemical liquid to the chamber to be reused.

According to embodiments of the present disclosure by allowing some of the reused chemical liquid to be reused again during the process of exchanging with new chemical liquid, a stopping ratio of the chemical liquid supply equipment may be minimized, and by controlling the Si concentration within the supplied chemical liquid, defects occurring in the process and equipment may be minimized, and the homeostasis of the process and equipment may be maintained.

### BRIEF DESCRIPTION OF THE DRAWINGS

FIG. 1 is a diagram illustrating a portion of a chemical liquid supply system to explain a chemical liquid exchange method of draining and exchanging a reused chemical liquid with a new chemical liquid according to an embodiment.

FIG. 2 illustrates a configuration of a chemical liquid supply system according to an embodiment.

FIG. 3 illustrates a graph to explain a change in a Si concentration in a chemical liquid due to a reuse of the chemical liquid.

FIG. 4 illustrates a graph to explain a Si concentration in a comparative chemical liquid supply method.

FIG. 5 illustrates a graph to explain a Si concentration in a chemical liquid supply process by a chemical liquid supply system according to an embodiment.

FIG. 6 illustrates a diagram to explain a method of reusing a recovered chemical liquid according to an embodiment.

FIG. 7 illustrates a graph to explain an effect of controlling a temperature of a chemical liquid recovered from a chemical liquid recycling method according to FIG. 6.

### DETAILED DESCRIPTION

Hereinafter, example embodiments of the present disclosure will be described in detail with reference to the attached drawings so that the person of ordinary skill in the art may easily implement embodiments of the present disclosure. However, embodiments of the present disclosure may be modified in various ways and are not limited to the examples described herein.

In the drawings, elements irrelevant to the description of embodiments of the present disclosure may be omitted for simplicity of explanation, and like reference numerals designate like elements throughout the specification.

Further, since sizes and thicknesses of constituent members shown in the accompanying drawings may be arbitrarily given for better understanding and ease of description, embodiments of the present disclosure are not limited to the illustrated sizes and thicknesses. In the drawings, the thickness of layers, films, panels, regions, etc., may be exaggerated for clarity.

Throughout the specification, when it is described that a part is “connected” (or “in contact with” or “coupled”) to another part, the part may be “directly connected” to the other element or “connected” to the other part through a third part. In addition, unless explicitly described to the contrary, the word “comprise” (or “include”), and variations such as “comprises” (or “includes”) or “comprising” (or ‘including”), will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “on a plane” means viewing a target portion from the top, and the phrase “on a cross-section” means viewing a cross-section formed by vertically cutting a target portion from the side.

A chemical liquid exchange method and a chemical liquid supply system according to embodiments of the present disclosure provide a method of exchanging a chemical liquid and a system for supplying the chemical liquid to exchange it for a new chemical liquid after draining the chemical liquid that has been reused several times.

In addition, the chemical liquid recycling method according to embodiments of the present disclosure provides a method of recovering the chemical liquid from a recycling unit and delivering it to a supply unit in order to reuse the chemical liquid used in an etching process multiple times.

In embodiments of the present disclosure, the chemical liquid supply may be performed in a chemical liquid supply system 10 for a Si₃N₄ wet etching process capable of implementing fine patterns, and may be directed to a high temperature single type phosphoric acid process with high productivity, and a purpose may be to minimize a stopping ratio of the chemical liquid supply system 10 in which the methods of embodiments of the present disclosure are performed and to ensure that equipment and processes maintain homeostasis.

Hereinafter, a chemical liquid exchange method, a chemical liquid supply system, and a chemical liquid recycling method according to an embodiment of the present disclosure will be described in more detail with reference to the drawings.

In some drawings, to explain the chemical liquid exchange, supply, and recycling method according to embodiments of the present disclosure, a path along which the chemical liquid moves is shown centered on each tank, and valves and other devices related to the tank that are not shown are the same as those included in general chemical liquid supply equipment, so they are omitted from the drawing.

The chemical liquid exchange method and the chemical liquid supply method, according to embodiments of the present disclosure, may exchange and supply a chemical liquid. For example, the chemical liquid exchange method and the chemical liquid supply method may replace a chemical liquid that has been reused several times with a new chemical liquid after draining the reused chemical liquid.

If the chemical liquid is reused several times, particles are generated in the chemical liquid, and the initially obtained Si₃N₄—SiO₂ selectivity changes, causing problems in equipment and processes. Accordingly, after reusing the chemical liquid a certain number of times, it may be necessary to discard the reused chemical liquid and supply the new chemical liquid.

In general, when the chemical liquid reuse cycle has been repeated several times, a first recycling tank and a second recycling tank of a recycling unit, and a first sub-tank of a first supply unit are filled with the reused chemical liquid, and an initially filled phosphoric acid solution (a phosphoric acid chemical liquid) remains in the second sub-tank, which is a part of a second supply unit.

In a chemical liquid exchange method, a chemical liquid reused in a chamber is simultaneously recovered from all recycling tanks, then all of the chemical liquid is drained. Following, a new phosphoric acid solution is supplied and used as a new chemical liquid. The first sub-tank and the second sub-tank supply the chemical liquid prepared through the above process to the main tank, and the main tank supplies the chemical liquid to the chamber so that it may be used in the process.

Specifically, all the reused chemical liquid is recovered from the first recycling tank and the second recycling tank, and then all the chemical liquid filled in the first recycling tank and the second recycling tank and the reused chemical liquid filled in the first sub-tank are drained (a full drain).

After all of the reused chemical liquids are drained, a new chemical liquid of a phosphoric acid solution is supplied to the first sub-tank and the second sub-tank (a full refill), and the newly supplied phosphoric acid solution goes through a mixing process to secure a particular Si₃N₄—SiO₂ selectivity.

In other words, a method may include draining all chemical liquid recovered by the full drain and the full refill methods, again filling with the new chemical liquid to meet the selectivity, and then supplying the new chemical liquid to the chamber.

Here, with respect to the newly supplied chemical liquid, an activation time may be important, and other processes cannot proceed during the time during which the new chemical liquid is manufactured. In conclusion, the time to drain the reused chemical liquid, the time to prepare the new chemical liquid, and the time to supply the prepared chemical liquid must be secured, so there was problems in comparative embodiments that it takes quite a long time to exchange and supply the new chemical liquid.

In the case of a chemical liquid exchange method of a comparative embodiment described above, other processes could not proceed during the chemical liquid preparation time of at least three hours, which inevitably led to a high equipment stop ratio and low productivity.

The chemical liquid exchange method according to embodiments of the present disclosure may solve the problem of low productivity caused by the inability to proceed with other processes while exchanging with the new chemical liquid and may allow other processes to proceed while exchanging with the new chemical liquid to increase the productivity.

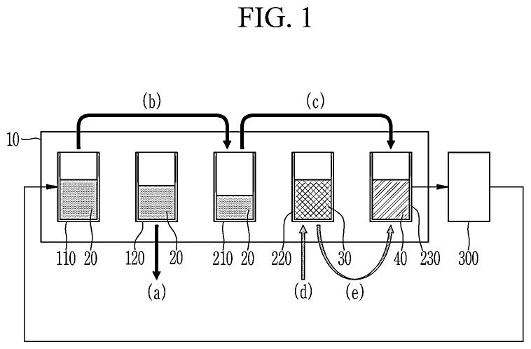

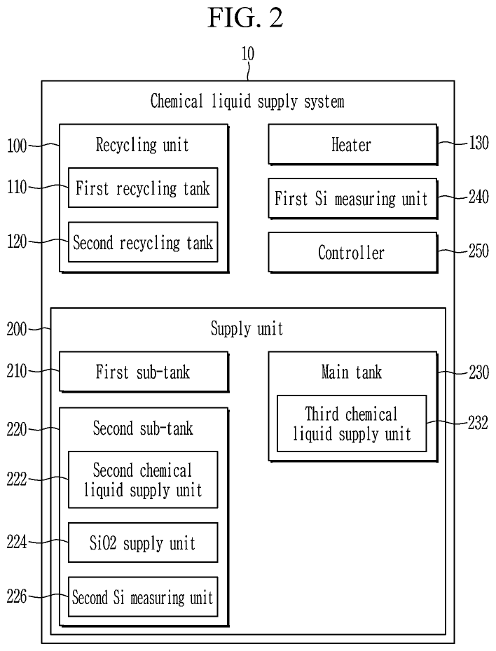

FIG. 1 is a diagram illustrating a portion of a chemical liquid supply system to explain a chemical liquid exchange method of draining and exchanging a reused chemical liquid with a new chemical liquid according to an embodiment. FIG. 2 illustrates a configuration of a chemical liquid supply system according to an embodiment.

Using the chemical liquid supply system 10 shown in FIG. 2, the chemical liquid exchange method described in FIG. 1 may be performed, and the chemical liquid supply system 10 may supply the new chemical liquid exchanged using the chemical liquid exchange method of FIG. 1 to the chamber.

With reference to FIG. 1, to explain the chemical liquid exchange method according to an embodiment of the present disclosure, only a first recycling tank 110, a second recycling tank 120, a first sub-tank 210, a second sub-tank 220, and a main tank 230 within a chemical liquid supply system 10 are shown, and valves, heaters and other devices related to the tank that are the same as general chemical liquid supply equipment may be omitted from the drawing for purposes of clarity.

As shown in FIG. 1, the chemical liquid exchange method according to an embodiment of the present disclosure includes a step of supplying a first chemical liquid 20 to the first sub-tank 210 from the first recycling tank 110 after the first recycling tank 110 recovers the first chemical liquid 20 used in the chamber 300 for reuse, a step of draining the first chemical liquid 20 by the second recycling tank 120 after the second recycling tank 120 recovers the first chemical liquid 20 used in the chamber 300, a step of supplying the first chemical liquid 20 from the first sub-tank 210 to the main tank 230, after the first sub-tank 210 receives the first chemical liquid 20 from the first recycling tank 110, and a step of receiving the second chemical liquid 30 by the second sub-tank 220 from an outside of the chemical liquid supply system 10 and supplying the second chemical liquid 30 from the second subtank 220 to the main tank 230.

In the wet etching process for a silicon nitride layer (Si₃N₄), the single type phosphoric acid process of high temperature is performed to ensure a productivity, and a phosphoric acid (H₃PO₄) solution of high temperature of 150 200 degrees is used as an etching solution, thereby the second chemical liquid 30 supplied from the outside may be a phosphoric acid solution.

The step in which the second recycling tank 120 drains the first chemical liquid 20, that was used in the chamber 300 and then recovered by the second recycling tank 120, is shown by arrow (a) in FIG. 1. The step, in which the first recycling tank 110 supplies the first chemical liquid 20 to the first sub-tank 210 for the reuse, after the first recycling tank 110 recovers the first chemical liquid 20 used in chamber 300, is indicated by arrow (b). The step, in which the first sub-tank 210 supplies the first chemical liquid 20 to the main tank 230, after receiving the first chemical liquid 20 from the first recycling tank 110, is indicated by arrow (c).

The order of each step, including the steps indicates by the arrow (a), the arrow (b), and the arrow (c), are not limited and may be performed simultaneously. The point of draining the first chemical liquid 20 from the second recycling tank 120 may at least be partially the same as in a comparative method, but, unlike the comparative method, the first chemical liquid 20 is not drained from the first recycling tank 110 and the first sub-tank 210 and is, instead, used again.

That is, in the chemical liquid exchange method according to an embodiment of the present disclosure, there is a benefit in that only one from among the first recycling tank 110 and the second recycling tank 120 from which the reused first chemical liquid 20 was recovered is drained, and the first chemical liquid 20 remaining in the other one from among the first recycling tank 110 and the second recycling tank 120 and the first sub-tank 210 is supplied to the main tank 230 for the reuse without the draining.

The step of supplying the second chemical liquid 30 from the outside to the second sub-tank 220 is indicated by an arrow (d), and the step of supplying the second chemical liquid 30 from the second sub-tank 220 to the main tank 230 is indicated by an arrow (e).

In the comparative method, in the step (d) of supplying the new chemical liquid and the step (e) of supplying the new chemical liquid to the main tank 230, the steps are performed after the drainage of all the first chemical liquid 20 from the first recycling tank 110, the second recycling tank 120, and the first sub-tank 210 is completed. The time required for the draining, the receiving of the new chemical liquid after the draining, and the mixing of the new chemical liquid were significant. The prepared chemical liquid could only be supplied to the main tank after the mixing was completed and thus, during the mixing, other equipment had to stop.

According to the chemical liquid exchange method according to an embodiment of the present disclosure, the steps indicated by arrow (d) and arrow (e) may be carried out simultaneously with the steps indicated by arrow (a), arrow (b), and arrow (c). In the chemical liquid exchange method according to an embodiment of the present disclosure, the step in which the first sub-tank 210 supplies the first chemical liquid 20 to the main tank 230 may be performed simultaneously with the step in which the second sub-tank 220 receives the second chemical liquid 30 and supplies the second chemical liquid 30 to the main tank 230.

Specifically, the process in which the first recycling tank 110 supplies the first chemical liquid 20 to the first sub-tank 210 and the first sub-tank 210 supplies the first chemical liquid 20 to the main tank 230 may be simultaneously performed with the step in which the second sub-tank 220 receives the second chemical liquid 30 and supplies the second chemical liquid 30 to the main tank 230.

In other words, the chemical liquid exchange method according to an embodiment of present disclosure may be characterized by the fact that the steps indicated by the arrow (d) and the arrow (e) may proceed simultaneously while the steps indicated by the arrow (b) and the arrow (c) are in progress.

Also, as shown in FIG. 1, the volume of the first chemical liquid 20 filled in the first recycling tank 110, that does not perform the draining, may be larger than the volume of the first chemical liquid 20 filled in the second recycling tank 120, that performs the draining.

That is, the volume of the first chemical liquid 20 recovered by the second recycling tank 120 is smaller than the volume of the first chemical liquid 20 recovered by the first recycling tank 110, and this has the effect of reducing the time required for the draining by draining the first chemical liquid 20 from the underfilled second recycling tank 120.

FIG. 1 shows an embodiment in which the drainage is performed in the second recycling tank 120, and shows a case where the amount of the first chemical liquid 20 filled in the second recycling tank 120 is less than the amount of the first chemical liquid 20 filled in the first recycling tank 110.

Conversely, if the volume of the first chemical liquid 20 recovered from the first recycling tank 110 is smaller than the volume of the first chemical liquid 20 recovered from the second recycling tank 120, the drainage may be performed by the first recycling tank 110, and the first chemical liquid 20 filled in the second recycling tank 120 may be supplied to the first sub-tank 210.

The new chemical liquid (e.g., the second chemical liquid 30) is supplied to the second sub-tank 220, and a preparation time may be needed to supply the second chemical liquid 30 to the main tank 230 due to the second sub-tank 220 receiving the second chemical liquid 30.

Accordingly, the step in which the second sub-tank 220 receives the second chemical liquid 30 and supplies the second chemical liquid 30 to the main tank 230 may include a step of controlling (e.g., by the second sub-tank 220) an etch selectivity of Si₃N₄—SiO₂ of the second chemical liquid 30 to control a mixing ratio of the second chemical liquid 30.

The main tank 230 may perform a step of supplying a third chemical liquid 40, that includes a mix of the first chemical liquid 20 supplied from the first sub-tank 210 and the second chemical liquid 30 (of which etch selectivity is controlled in the second sub-tank 220), to the chamber 300.

In addition, the chemical liquid exchange method according to an embodiment of the present disclosure may be different from the comparative chemical liquid exchange method even in the process of recovering a portion of the reused first chemical liquid 20 and supplying the first chemical liquid 20 to the first sub-tank 210.

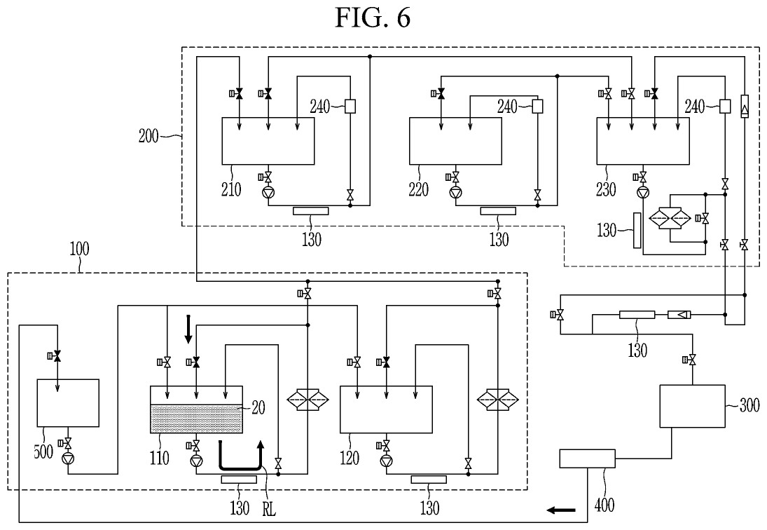

Specifically, the first recycling tank 110 and the second recycling tank 120 may be provided with a recycling circulation line RL (refer to FIG. 6) that circulates the chemical liquid to and from each tank.

The first chemical liquid 20 recovered from the chamber 300 is recovered by each of the first recycling tank 110 and the second recycling tank 120, moves along each recycling circulation line RL, and then returns to the first recycling tank 110 and the second recycling tank 120. A heater 130 (refer to FIG. 2) may be placed in each recycling circulation line RL, and the temperature of the first chemical liquid 20 may be raised by the heater 130.

In the chemical liquid exchange method according to an embodiment of the present disclosure, the first recycling tank 110, that recovers the first chemical liquid 20, may raise the temperature of the first chemical liquid 20 using a heater 130 connected to the first recycling tank 110 and then supply the first chemical liquid 20 to the first sub-tank 210.

That is, in the chemical liquid exchange method according to an embodiment of the present disclosure and in contrast to the comparative method, the heater 130 capable of raising the temperature of the first chemical liquid 20 in the first recycling tank 110 may be disposed and may perform heating while the first chemical liquid 20 is being recovered by the first recycling tank 110 for reuse.

Before supplying the first chemical liquid 20 to the first sub-tank 210, the temperature increasing efficiency of the first chemical liquid 20 may be increased by raising the temperature of the first chemical liquid 20 to some extent in the circulation line RL (refer to FIG. 6) of the first recycling tank 110 or the second recycling tank 120.

If the first chemical liquid 20 is not heated in the recycling circulation line RL and is supplied directly to the first sub-tank 210, as the overall supply line through which the first chemical liquid circulates becomes longer, it takes more time to raise the temperature of the first chemical liquid 20 to the same temperature. In contrast, the recycling circulation line RL is a relatively small circulation line, and has the merit of being able to raise the temperature of the first chemical liquid 20 within the recycling circulation line RL to a certain temperature within a short period of time.

In the above description, an embodiment in which the temperature of the first chemical liquid 20 is raised by the heater 130 disposed in the circulation line RL of the first recycling tank 110 and the first chemical liquid 20 is supplied to the first sub-tank 210 is explained. According to an embodiment, in the case where the first chemical liquid 20 is recovered by the second recycling tank 120 and the first chemical liquid 20 is supplied from the second recycling tank 120 to the first sub-tank 210, the temperature of the first chemical liquid 20 may be raised by the heater 130 disposed in the circulation line provided with the second recycling tank 120.

The first chemical liquid 20 supplied from the first sub-tank 210, which receives the first chemical liquid 20 in a heated state, and the second chemical liquid 30, of which the etch selectivity was adjusted in the second sub-tank 220, may be supplied to the main tank 230, and then the main tank 230 may supply the third chemical liquid 40, that includes the mix of the first chemical liquid 20 and the second chemical liquid 30, to the chamber 300.

As described above with reference to FIG. 1, a chemical liquid exchange method that includes supplying of the new second chemical liquid 30 is provided. With reference to FIG. 2, the chemical liquid supply system 10 will be further explained below.

FIG. 2 shows the configuration of the chemical liquid supply system 10 that performs the chemical liquid exchange, including the supply of the of second chemical liquid 30 to the chamber 300, described above with reference to FIG. 1. The chemical liquid supply system 10 of FIG. 2 may supply the new chemical liquid exchanged in the chemical liquid exchange method described above to the chamber 300.

Particularly, the chemical liquid supply system 10 according to an embodiment of the present disclosure may maintain the Si concentration in the chemical liquid supplied to the chamber 300 within an appropriate range and supply the chemical liquid to the chamber 300, thereby preventing problems such as hardware defects due to a Si precipitation during the process and process defects due to low selectivity.

Referring to FIG. 1 and FIG. 2, the chemical liquid supply system 10 according to an embodiment of the present disclosure includes a recycling unit 100 that includes a first recycling tank 110 and a second recycling tank 120. The recycling unit 100 may recover the first chemical liquid 20 from the chamber 300. In addition, the chemical liquid supply system 10 may further include a supply unit 200 that mixes the first chemical liquid 20 supplied from the recycling unit 100 and the newly supplied second chemical liquid 30 to create the third chemical liquid 40, and then supplies the third chemical liquid 40 to the chamber 300. The supply unit 200 may include a first sub-tank 210, a second sub-tank 220, and a main tank 230.

The supply unit 200 may control the temperature and the concentration of the third chemical liquid 40 supplied to the chamber 300. Accordingly, the first sub-tank 210, the second sub-tank 220, and the main tank 230 of the supply unit 200 may include at least one heater 130 capable of raising the temperature of the chemical liquids stored in each. Each tank may be connected to a circulation line that enables chemical liquid to come out of the tank and reenter the same tank, and the heater 130 may be placed in each circulation line to raise the temperature of the chemical liquid circulating in the circulation line to a certain temperature.

The chemical liquid supply system 10 according to an embodiment of the present disclosure is a chemical liquid supply system that supplies the exchanged chemical liquid to the chamber 300, and includes the first recycling tank 110 and the second recycling tank 120 that are connected to the chamber 300 and receive the first chemical liquid 20 from the chamber 300. Also, the chemical liquid supply system 10 may include the first sub-tank 210 that is connected to the first recycling tank 110 and receives the first chemical liquid 20 from the first recycling tank 110, the second sub-tank 220 that receives the second chemical liquid 30 from the second chemical liquid supply unit 222, and the main tank 230 that is connected to the first sub-tank 210 and the second sub-tank 220 and mixes the first chemical liquid 20 supplied from the first sub-tank 210 and the second chemical liquid 30 supplied from the second sub-tank 220 to generate the third chemical liquid 40.

According to embodiments, the main tank 230 may include a third chemical liquid supply unit 232 (e.g., a third chemical liquid supply) that supplies the third chemical liquid 40 from the main tank 230 to the chamber 300.

According to embodiments, the chemical liquid supply system 10 may further include a first Si measuring unit 240 that is disposed in the third chemical liquid supply unit 232 and measures the Si concentration of the third chemical liquid 40 supplied to the chamber 300.

According to embodiments, the chemical liquid supply system 10 may further include a controller 250 that controls the amount of SiO2 included in the second chemical liquid 30 supplied to the second sub-tank 220 according to the measured Si concentration of the third chemical liquid 40. According to embodiments, the controller 250 may include at least one processor and memory storing computer instructions. The computer instructions, when executed by the at least one processor, may cause the controller 250 to perform its functions.

If the Si concentration of the third chemical liquid 40 measured by the first Si measuring unit 240 (e.g., a first Si measurer) is below a predetermined reference, the controller 250 may control the supply of more SiO2 to the second chemical liquid 30 supplied to the second sub-tank 220. If the Si concentration of the third chemical liquid 40 measured in the first Si measuring unit 240 is greater than a predetermined reference, SiO₂ may be removed in the second sub-tank 220 or second chemical liquid 30 with a lower SiO2 concentration than the first chemical liquid may be supplied.

According to an embodiment, the chemical liquid supply system 10 may further include a second Si measuring unit 226 (e.g., a second SI measurer) disposed on the second chemical liquid supply unit 222 and that measures the Si concentration of the second chemical liquid 30 supplied to the second sub-tank 220.

Also, the chemical liquid supply system 10 may further include a SiO₂ supply unit 224 (e.g., a SiO₂ supply) connected to the second chemical liquid supply unit 222 that supplies SiO₂ to the second chemical liquid 30, thereby controlling the amount of SiO₂ to be included in the second chemical liquid 30.

The controller 250 may control the drainage of the first chemical liquid 20 stored in the first recycling tank 110 and the first sub-tank 210 according to the Si concentration measured by the first Si measuring unit 240. That is, the chemical liquid supply system 10 according to an embodiment of the present disclosure may control the SiO₂ concentration in the second chemical liquid 30 depending on the Si concentration of the third chemical liquid 40 measured by the first Si measuring unit 240 and may control the amount of the first chemical liquid 20 supplied to the main tank 230, thereby controlling the concentration of Si in the third chemical liquid 40 by various methods.

According to an embodiment, the controller 250, after draining the first chemical liquid 20 stored in the first recycling tank 110, may control the second chemical liquid 30 having the lower SiO2 concentration than the first chemical liquid to be supplied to the second sub-tank 220 based on the Si concentration of the third chemical liquid 40 measured by the first Si measuring unit 240 being greater than a preset reference value.

According to another embodiment, the controller 250, after draining the first chemical liquid 20 stored in the first sub-tank 210, may supply the second chemical liquid 30 having the lower SiO2 concentration than the first chemical liquid to the second sub-tank 220 based on the Si concentration of the third chemical liquid 40 measured by the first Si measuring unit 240 being greater than a preset reference value.

Hereinafter, the method of supplying the chemical liquid by the chemical liquid supply system 10 according to an embodiment of the present disclosure is described in detail.

The chemical liquid supply method, performed by the chemical liquid supply system 10, may include the step of supplying the first chemical liquid 20 supplied from the first sub-tank 210 to the main tank 230, the step of supplying the second chemical liquid 30 to the second sub-tank 220 by the second chemical liquid supply unit 222, the step of supplying the second chemical liquid 30 to the main tank 230 by the second sub-tank 220, the step of generating, by the main tank 230, the third chemical liquid 40 that includes a mix of the first chemical liquid 20 and the second chemical liquid 30, the step of supplying the third chemical liquid 40 to the chamber 300 by the main tank 230, and the step of measuring the Si concentration of the third chemical liquid 40 by the first Si measuring unit 240.

In a chemical liquid supply device, it may be seen that as the number of the reuses of the chemical liquid increases, the Si concentration included in the chemical liquid being used gradually increases, and this causes problems as SiO2 is generated as a by-product of the etching reaction of Si₃N₄.

The chemical liquid supply method according to an embodiment of the present disclosure may avoid the above problems. For example, the first Si measuring unit 240 may measure the Si concentration of the third chemical liquid 40.

According to the embodiment, the first Si measuring unit 240 may be disposed on the third chemical liquid supply unit 232 and may measure the Si concentration of the third chemical liquid 40 suppled to the chamber 300.

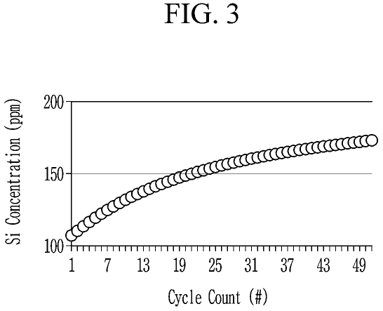

FIG. 3 illustrates a graph to explain a change in a Si concentration in a chemical liquid due to a reuse of the chemical liquid.

As shown in FIG. 3, it may be confirmed that as the number of the reuse times of the chemical liquid in the chemical liquid supply device increases, the Si concentration in the chemical liquid increases. This is the result of the accumulation of SiO₂ in the phosphoric acid solution as the chemical liquid is reused several times.

The Si concentration is a factor that affects the maintenance of a homeostasis of a Si₃N₄—SiO₂ etch selectivity, so the Si concentration within the device is important in the chemical liquid supply device. If the amount of Si included in the chemical liquid is greater than a predetermined reference value, the Si precipitation may cause hardware defects, resulting in process defects. If the amount of Si included in the chemical liquid is less than the predetermined reference value, the selectivity may be lowered and the process defects may occur, making it difficult to maintain process progress homeostasis.

In contrast, in the chemical liquid supply method according to an embodiment of the present disclosure, the first Si measuring unit 240 may measure the concentration of the third chemical liquid 40 supplied from the main tank 230 to the chamber 300, and the Si concentration of the third chemical liquid 40 may be controlled (e.g., adjusted) depending on the concentration value of the third chemical liquid 40 obtained by the controller 250 via the first Si measuring unit 240.

The appropriate concentration of Si included in the third chemical liquid 40 may vary depending on the reference value predetermined by the user. The user may pre-set the appropriate concentration range of the third chemical liquid 40 and perform a feedback control on the Si concentration within the appropriate concentration range.

If the Si concentration measured by the first Si measuring unit 240 is outside the preset reference range, the controller 250 may adjust the Si concentration in the third chemical liquid 40 to be within the preset reference range above.

According to an embodiment, when the Si concentration of the third chemical liquid 40 measured in the first Si measuring unit 240 is below a preset reference value, the controller 250 may cause SiO₂ to be added to the second chemical liquid 30 supplied to the second sub-tank 220. SiO₂ may be added through a SiO₂ supply unit 224 connected to the second chemical liquid supply unit 222, the SiO₂ supply unit 224 configured to supply SiO₂ to the second chemical liquid 30.

Also, if the Si concentration of the third chemical liquid 40 measured in by first Si measuring unit 240 is above the preset reference value, the controller 250 may cause the second chemical liquid 30 from which SiO2 has been removed to be supplied to the second sub-tank 220.

In another embodiment, when the Si concentration of the third chemical liquid 40 measured by the first Si measuring unit 240 is greater than a preset reference value, the controller 250 may cause draining of the first chemical liquid 20 stored in the first recycling tank 110 and then supplying of the second chemical liquid 30 having a lower SiO2 concentration than the first chemical liquid to the second sub-tank 220. This is an example of the case where the first chemical liquid 20 recovered by the first recycling tank 110 is reused, and the first chemical liquid 20 recovered by the second recycling tank 120 is drained. As explained above, the tank that performs draining may vary depending on the amount of the filled first chemical liquid 20 between the first recycling tank 110 and the second recycling tank 120.

In another embodiment, when the Si concentration of the third chemical liquid 40 measured by the first Si measuring unit 240 is greater than a preset reference value, the controller 250 may causing draining of the first chemical liquid 20 stored in the first sub-tank 210 and then supplying of the second chemical liquid 30, which has a lower SiO2 concentration than the first chemical liquid, to the second sub-tank 220.

According to an embodiment, the second Si measuring unit 226 may be placed on the second chemical liquid supply unit 222 that supplies the second chemical liquid 30 to the second sub-tank 220, and the second Si measuring unit 226 may measure the Si concentration of the second chemical liquid 30 supplied to the second sub-tank 220. In this case, by measuring the concentration of SiO2 included in the newly supplied second chemical liquid 30, the Si concentration included in the second chemical liquid 30 may be adjusted (e.g., by the controller 250) by reducing or increasing the concentration of SiO2 included in the second chemical liquid 30 to be supplied.

In some cases, the SiO2 supply unit 224 (e.g., due to control by the controller 250) may additionally supply SiO2 to the second chemical liquid 30 supplied to the second sub-tank 220 according to the Si concentration measured by the second Si measuring unit 226.

The second Si measuring unit 226, placed on the second chemical liquid supply unit 222 and measuring the Si concentration of the second chemical liquid 30, may have a different measurement target from the first Si measuring unit 240, placed on the third chemical liquid supply unit 232 and measuring the Si concentration of the third chemical liquid 40 supplied to the chamber 300.

Even if the Si concentration of the second chemical liquid 30 is measured and the second chemical liquid 30 of which the Si concentration is adjusted within the preset range is supplied to the second sub-tank 220, the concentration of Si in the third chemical liquid 40, which is the mixture of the first chemical liquid 20 and the second chemical liquid 30 supplied in the main tank 230, may be outside the preset range. Therefore, the role of the first Si measuring unit 240 to measure the Si concentration of the third chemical liquid 40 may be important.

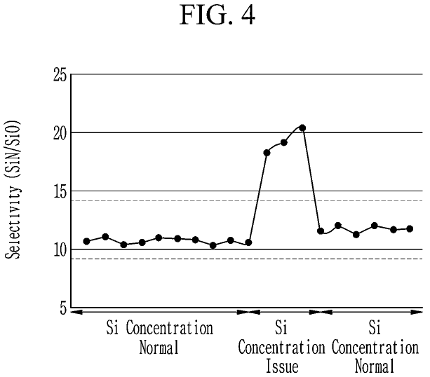

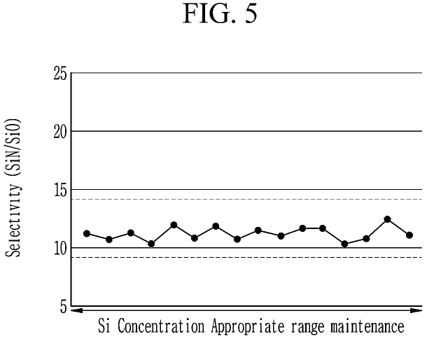

FIG. 4 illustrates a graph to explain a Si concentration in a comparative chemical liquid supply method. FIG. 5 illustrates a graph to explain a Si concentration in a chemical liquid supply process according to an embodiment of the present disclosure.

In the graph shown in FIG. 4 and FIG. 5, as one example, the appropriate Si concentration range preset by the user is shown as a value between 8 and 14 of a selectivity (SiN/SiO).

FIG. 4 shows the change in the concentration of Si in the chemical liquid in the comparative chemical liquid supply method, and FIG. 4 demonstrates that there are cases where the concentration of Si is outside the appropriate Si concentration range set in advance.

FIG. 5 shows the change in the concentration of Si in the chemical liquid supply method according to an embodiment of the present disclosure, and FIG. 5 demonstrates that there is no case where the concentration of Si deviates from the appropriate Si concentration range set in advance.

This is because, for example, the first Si measuring unit 240 placed on the third chemical liquid supply unit 232 measures the Si concentration of the third chemical liquid 40, SiO₂ is added to the second chemical liquid 30 supplied to the second sub-tank 220 by the SiO₂ supply unit 224 depending on the measured Si concentration, and pure phosphoric acid solution is used as the second chemical liquid 30 to control the amount of Si as described above.

Accordingly, there are no problems that the amount of Si included in the third chemical liquid 40 is greater than the predetermined reference value, thereby avoiding Si precipitation that results in hardware defects and process defects. Additionally, there are no problems of the selectivity being lower than the predetermined reference value, thereby avoiding occurrence of process defects which make it difficult to maintain the process homeostasis.

As a result, by supplying the third chemical liquid 40 including Si of the appropriate concentration, the chemical liquid supply method according to an embodiment of the present disclosure may lower the stop ratio of the process and maintain process homeostasis.

FIG. 6 illustrates a diagram to explain a method of reusing a recovered chemical liquid according to an embodiment. According to embodiments, the method may be referred to as a chemical liquid recycling method.

The chemical liquid recycling method according to an embodiment of the present disclosure may include the process in which the recycling unit 100 recovers the reused first chemical liquid 20 from the chamber 300 and supplies the recovered first chemical liquid 20 to the supply unit 200, and may include the recovery method and the supply method of the first chemical liquid 20 performed with respect to the recycling unit 100.

The chemical liquid recycling method according to FIG. 6 may be a part of the chemical liquid recovery process that is repeated several times. While FIG. 1 and FIG. 2 have been referenced above to describe aspects of exchanging the chemical liquid, after being reused several times, into the new chemical liquid and supplying the new chemical liquid to the chamber, reference is made below with respect to FIG. 6 to describe aspects of the process of recovering the newly exchanged chemical liquid and reusing it repeatedly (e.g., the chemical liquid recycling method).

According to embodiments of the present disclosure, a method may be provided that includes a combination of the chemical liquid recycling method, described below with reference to FIG. 6, and the process of supplying the new chemical liquid, that was exchanged according to the chemical liquid exchange method described above with respect to FIG. 1 and FIG. 2, to the chamber and then recovering it from the recycling unit 100.

According to embodiments, the chemical liquid recycling method is a method of recovering and reusing the chemical liquid from the chamber 300. For example, at least one from among the first recycling tank 110 and the second recycling tank 120 may recover the first chemical liquid 20 from the chamber 300. For example, the first chemical liquid 20 used in the chamber 300 passes through a buffer tank 400 and a vacuum tank 500 and moves to the first recycling tank 110 and the second recycling tank 120.

Next, the recovered first chemical liquid 20 may be supplied to the supply unit 200 including the first sub-tank 210, the second sub-tank 220, and the main tank 230, and the first chemical liquid 20 may be supplied from the supply unit 200 to the chamber 300.

In the chemical liquid recycling method according to an embodiment of the present disclosure, the chemical liquid supplied from the supply unit 200 to the chamber 300 is described as the first chemical liquid 20, but the phosphoric acid solution (the second chemical liquid 30), which is supplied at the beginning of the chemical liquid reuse cycle, and the first chemical liquid 20 may be mixed and supplied to the chamber 300. For example, at the beginning when the reuse cycle starts, the phosphoric acid solution (the second chemical liquid 30) filled in the first sub-tank 210 and the second sub-tank 220 may be mixed with the first chemical liquid 20 supplied from recycling unit 100 and supplied to the chamber 300.

However, for the purpose of clarity, explanation may focus mainly on the flow of the first chemical liquid 20, and further detailed explanation of the second chemical liquid 30 may be omitted. A person of ordinary skill in the art may appreciate that the recycling method according to an embodiment of the present disclosure may include aspects of a general chemical liquid reuse cycle, and would understand, based on the present disclosure, details of the flow of the second chemical liquid 30.

With reference to FIG. 6, the chemical liquid recycling method according to an embodiment of the present disclosure includes recovering the first chemical liquid 20 from the chamber 300 by one from among the first recycling tank 110 and the second recycling tank 120 of the recycling unit 100. This enables the efficient recovery and supply the first chemical liquid 20, and reduces the preparation time for the chemical liquid to be supplied to the chamber 300 by shortening the time to recover the first chemical liquid 20. Additionally, this allows the first chemical liquid 20 to be filled first in one tank to reduce the time it takes to recover and supply the first chemical liquid 20 to the supply unit 200 compared to recovering by two tanks, as explained below, and efficiently increases the temperature of the first chemical liquid 20.

In the chemical liquid recycling method according to an embodiment of the present disclosure, the first chemical liquid 20 may be heated in the recycling unit 100 before supplying the first chemical liquid 20 recovered by the recycling unit 100 to the supply unit 200.

In a comparative case, the first chemical liquid 20 is simultaneously recovered by both the first recycling tank 110 and the second recycling tank 120 included in recycling unit 100, and the recovered first chemical liquid 20 is supplied to the supply unit 200. Accordingly, the first chemical liquid 20 moves along a larger circulation line from the recycling unit 100 to the supply unit 200.

In the case of the chemical liquid recycling method according to an embodiment of the present disclosure, the first chemical liquid 20 recovered by recycling unit 100 is not directly supplied to the supply unit 200, but rather the first chemical liquid 20 is heated along a small circulation line within the recycling unit 100 and then supplied to the supply unit 200.

When supplying from the recycling unit 100 directly to the supply unit 200, the first chemical liquid 20 may move along a large circulation line from the recycling unit 100 to the supply unit 200, and the temperature of first chemical liquid 20 may need to be raised in the large circulation line. However, according to the chemical liquid recycling method according to an embodiment of the present disclosure, chemical liquid moves along a small circulation line (e.g., the recycling circulation line RL), and the temperature of the first chemical liquid 20 may be raised in the small circulation line.

With reference to FIG. 6, in the chemical liquid recycling method according to an embodiment of the present disclosure, the first recycling tank 110 and the second recycling tank 120 have a recycling circulation line RL that circulates chemical liquid to and from each tank. Accordingly, the first chemical liquid 20 is recovered by each of the first recycling tank 110 and second recycling tank 120, then moves along each circulation line RL, and then is returned to the first recycling tank 110 and the second recycling tank 120.

According to embodiments, the first chemical liquid 20 is recovered by the recycling unit 100 along with water that is used in a cleaning in the recovery process, and the temperature of the first chemical liquid 20 drops due to heat loss during the recovery process. Accordingly, embodiments of the present disclosure may adjust the concentration and the temperature by raising the temperature of the first chemical liquid 20.

The chemical liquid recycling method according to an embodiment of the present disclosure may include controlling the temperature of the first chemical liquid 20 while the first chemical liquid 20 is circulated along the recycling circulation line RL connected to the first recycling tank 110 and/or the second recycling tank 120.

This has the effect of efficiently increasing concentration of the chemical liquid before being supplied to the supply unit 200 by evaporating the water in the chemical liquid by raising the temperature within the recycling circulation line RL, thereby raising the temperature of the first chemical liquid 20.

According to an embodiment, the temperature of the first chemical liquid 20 may be controlled by circulating the first chemical liquid 20 within the recycling circulation line RL, wherein the heater 130 is placed in each recycling circulation line RL.

According to an embodiment, the heater 130 (via control by the controller 250) may heat the first chemical liquid 20 to a first temperature (e.g., a predetermined temperature) to control the concentration of the first chemical liquid 20.

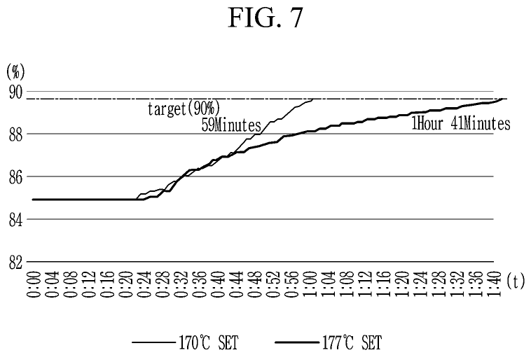

According to an embodiment, the temperature of the heater 130 may be set higher than the first temperature. Setting the temperature of the heater 130 higher than the target temperature (e.g., the first temperature) of the first chemical liquid 20 may provide a benefit of shortening the time required to raise the temperature of the first chemical liquid 20 in the recycling circulation line RL to obtain a target concentration of the first chemical liquid 20. This benefit may be confirmed based on FIG. 7.

FIG. 7 illustrates a graph to explain an effect of controlling a temperature of a chemical liquid recovered from a chemical liquid recycling method according to FIG. 6.

In FIG. 7, a case where a target concentration of the first chemical liquid 20 is 90% is given as an example, and a reference concentration line of 90% (“target (90%)”) is indicated.

The target theoretical concentration is 90%, even if it is not exactly set to 90%, a case reaching close to 90% (e.g., 89.5%) may also be considered to reach the target concentration.

Curved lines shown on the graph represent a change in the concentration of the first chemical liquid 20 over time according to the heater 130 being controlled to heat at various predetermined temperatures. Also, the time taken to reach the target concentration of 90% may be determined based on a comparison of the curved lines to the reference concentration line of 90% (“target (90%)”).

With reference to FIG. 7, it is assumed that the target temperature of the first chemical liquid 20 is 170 degrees Celsius. The bolded curved line in FIG. 7 indicates a change in the concentration of the first chemical liquid 20 heated by the heater 130 at a predetermined temperature of 170 degrees Celsius, and the non-bolded curved line in FIG. 7 indicates a change in the concentration of the first chemical liquid 20 heated by the heater 130 at a predetermined temperature of 177 degrees Celsius.

As shown in FIG. 8, the first chemical liquid 20 heated by the heater 130 at the predetermined temperature of 177 degrees Celsius reaches the reference concentration line of 90% more quickly than when the first chemical liquid 20 is heated by the heater 130 at the predetermined temperature of 170 degrees Celsius.

According to embodiments, setting the temperature of the heater 130 higher than the target temperature (e.g., the first temperature) may shorten the time to reach the target concentration, thereby accelerating the evaporation speed of water included in the first chemical liquid 20.

According to an embodiment, as the concentration of the first chemical liquid 20 approaches the target concentration of 90% (e.g., the reference concentration line of 90%), the controller 250 may control the heater 130 to heat at a decreased predetermined temperature so that there is no problem of exceeding the target concentration.

The heater 130 may be placed in each recycling circulation line RL, and the heater 130 may not only adjust the concentration of the first chemical liquid 20, but also increase its temperature.

According to an embodiment of the present disclosure, the heater 130 capable of raising the temperature of the first chemical liquid 20 is placed on the recycling circulation line RL connected to the first recycling tank 110 and the second recycling tank 120. Accordingly, before supplying the first chemical liquid 20 to the first sub-tank 210, the temperature of the first chemical liquid 20 may be raised to a certain extent in the recycling circulation line RL of the first recycling tank 110 and the second recycling tank 120, thereby increasing the temperature raising efficiency of the first chemical liquid 20.

By reducing the temperature rising time of the first chemical liquid 20, the time to reach the target concentration of first chemical liquid 20 may be shortened, and it is possible to shorten the chemical liquid preparation time from preparing the first chemical liquid 20 to supplying the first chemical liquid 20 to the main tank 230.

As described above, the first chemical liquid 20 recovered by either the first recycling tank 110 or the second recycling tank 120 may be supplied to the supply unit 200 after being heated through the recycling circulation line RL. For example, the recycling unit 100 may supply the first chemical liquid 20, which has a preset concentration due to temperature control, to the supply unit 200, and the first chemical liquid 20 with the controlled temperature and the concentration may be supplied to the chamber 300 by the supply unit 200, thereby being reused.

As above described, the chemical liquid exchange method, the chemical liquid supply system, and the chemical liquid recycling method according to embodiments of the present disclosure may include a single type phosphoric acid process of high temperature, and may enable the supply of a reused chemical liquid even while manufacturing a new chemical liquid, thereby lowering a stop ratio of equipment and processes that supply the chemical liquid.

In addition, by controlling the Si concentration in the chemical liquid to be maintained within the appropriate range, it is possible to prevent hardware defects due to the Si precipitation or process defects due to the low selectivity, thereby preventing difficulty in maintaining process progress homeostasis.

In addition, by minimizing the time required to recover the chemical liquid and raising the temperature to meet a target concentration, the stopping ratio of the process may be lowered and the homeostasis of the process may be maintained by supplying the chemical liquid of the appropriate concentration.

According to embodiments of the present disclosure, the controller 250 may be configured to control the chemical liquid supply system 10, including one or more (e.g., some or all) of its components to perform its functions. For example, the controller 250 may control the chemical liquid supply system 10, including the one or more of its components, to perform the various methods described in the present disclosure. As a part of the control, the controller 250 may control, for example, the various valves and pumps (see FIG. 6) that may be included in the chemical liquid supply system 10, and the control of the various valves and pumps may be a part of the various methods described in the present disclosure.

While non-limiting example embodiments have been described above in connection with the drawings, it is to be understood that embodiments of the present disclosure are not limited to the exampled embodiments. On the contrary, various modifications and equivalent arrangements are included within the spirit and scope of the present disclosure.

What is claimed is:

1. A chemical liquid exchange method comprising:
recovering, by a first recycling tank, a first portion of a first chemical liquid that was previously used in a chamber;
recovering, by a second recycling tank, a second portion of the first chemical liquid that was previously used in the chamber;
supplying, from the first recycling tank, the first portion of the first chemical liquid to a first sub-tank;
draining, from the second recycling tank, the second portion of the first chemical liquid;
supplying, from the first sub-tank, the first portion of the first chemical liquid to a main tank; and
receiving, by a second sub-tank, a second chemical liquid from an outside; and
supplying, from the second sub-tank, the second chemical liquid to the main tank.

2. The chemical liquid exchange method of claim 1, wherein the supplying, from the first sub-tank, the first portion of the first chemical liquid is performed simultaneously with the receiving, by the second sub-tank, the second chemical liquid and the supplying, from the second sub-tank, the second chemical liquid to the main tank.

3. The chemical liquid exchange method of claim 1, wherein a volume of the second portion of the first chemical liquid recovered by the second recycling tank is smaller than a volume of the first portion of the first chemical liquid recovered by the first recycling tank.

4. The chemical liquid exchange method of claim 2, wherein the receiving the second chemical liquid by the second sub-tank or the supplying the second chemical liquid to the main tank comprises adjusting an etch selectivity of Si₃N₄—SiO₂ of the second chemical liquid.

5. The chemical liquid exchange method of claim 1, further comprising:
increasing, by a heater connected to the first recycling tank, a temperature of the first portion of the first chemical liquid before the supplying the first portion of the first chemical liquid to the first sub-tank.

6. The chemical liquid exchange method of claim 1, further comprising:
obtaining, by the main tank, a third chemical liquid from the first portion of the first chemical liquid and the second chemical liquid mixing in the main tank; and
supplying, from the main tank, the third chemical liquid to the chamber.

7. A chemical liquid supply system comprising:
a first recycling tank connected to a chamber and configured receive, from the chamber, a first portion of a first chemical liquid that was used in the chamber;
a second recycling tank connected to the chamber and configured receive, from the chamber, a second portion of the first chemical liquid that was used in the chamber;
a first sub-tank connected to the first recycling tank and configured to receive the first portion of the first chemical liquid from the first recycling tank;
a second sub-tank configured to receive a second chemical liquid from a second chemical liquid supply;
a main tank connected to the first sub-tank and the second sub-tank, the main tank configured to receive the first portion of the first chemical liquid from the first sub-tank and the second chemical liquid from the second sub-tank, and obtain a third chemical liquid by the first portion of the first chemical liquid and the second chemical liquid mixing in the main tank;
a third chemical liquid supply configured to supply the third chemical liquid from the main tank to the chamber;
a first Si measurer in the third chemical liquid supply and configured to measure a Si concentration of the third chemical liquid supplied to the chamber; and
a controller configured to control an amount of SiO₂ included in the second chemical liquid supplied to the second sub-tank based on a measured Si concentration of the third chemical liquid.

8. The chemical liquid supply system of claim 7, further comprising:
a second Si measurer in the second chemical liquid supply and configured to measure a Si concentration of the second chemical liquid supplied to the second sub-tank.

9. The chemical liquid supply system of claim 7, further comprising:
a SiO2 supply connected to the second chemical liquid supply and configured to supply the SiO2 to the second chemical liquid.

10. The chemical liquid supply system of claim 7, wherein the controller is configured to control, based on the Si concentration of the third chemical liquid measured by the first Si measurer being below a preset reference value, SiO2 to be supplied to the second chemical liquid supplied to the second sub-tank.

11. The chemical liquid supply system of claim 7, wherein the controller is configured to control, based on the Si concentration of the third chemical liquid measured by the first Si measurer being above a preset reference value, supply of the second chemical liquid, from which SiO2 has been removed, to the second sub-tank.

12. The chemical liquid supply system of claim 7, wherein the controller is configured to regulate drainage of the first chemical liquid stored in the first recycling tank and the first sub-tank depending on the measured Si concentration of the third chemical liquid.

13. The chemical liquid supply system of claim 12, wherein the controller is configured to cause, based on the Si concentration of the third chemical liquid measured by the first Si measurer being above a preset reference value, supply of the second chemical liquid with a lower SiO2 concentration than the first chemical liquid to the second sub-tank after draining the first chemical liquid stored in the first recycling tank.

14. The chemical liquid supply system of claim 12, wherein the controller is configured to cause, based on the Si concentration of the third chemical liquid measured by the first Si measurer being above a preset reference value, supply of the second chemical liquid from which SiO2 is removed to the second sub-tank after draining the first portion of the first chemical liquid stored in the first sub-tank.

15. A method of recovering and reusing a chemical liquid, the method comprising:
recovering a first chemical liquid from a chamber by one from among a first recycling tank and a second recycling tank of a recycling unit;
supplying the first chemical liquid to a supply unit, that comprises at least one sub-tank, after raising a temperature of the first chemical liquid in the one from among the first recycling tank and the second recycling tank; and
supplying, from the supply unit, the first chemical liquid to the chamber to be reused.

16. The method of claim 15, further comprising:
controlling, by a recycle circulation line connected to the one from among the first recycling tank and the second recycling tank, a temperature of the first chemical liquid.

17. The method of claim 16, wherein the controlling the temperature comprises controlling the temperature of the first chemical liquid by a heater in the recycle circulation line.

18. The method of claim 17, wherein the controlling the temperature comprises controlling a concentration of the first chemical liquid to be a preset concentration by raising, by the heater, the temperature of the first chemical liquid to a first preset temperature.

19. The method of claim 18, wherein the supplying the first chemical liquid comprises supplying, by the recycling unit, the first chemical liquid with the preset concentration to the supply unit.

20. The method of claim 18, wherein the controlling the temperature comprising raising the temperature of the first chemical liquid to the first preset temperature by setting a temperature of the heater to be higher than the first preset temperature.
